(19) United States
(12) Patent Application Publication
(10) Pub. No.: US 2004/0124865 A1
(43) Pub. Date: Jul. 1, 2004

(54) Method and structure for wafer-level reliability electromigration and stress migration test by isothermal heater

(76) Inventors: Kun Fu Chuang, Hsinchu (TW); Fu-Chien Chiu, Taipei (TW); Rueyway Lin, Hsin-Chu (TW); Jenn-Chang Hwang, Hsinchu City (TW)

Correspondence Address: BIRCH STEWART KOLASCH & BIRCH, PO BOX 747, FALLS CHURCH, VA, 22040-0747, US

(21) Appl. No.: 10/327,984

(22) Filed: Dec. 26, 2002

(51) Int. Cl. G01R 31/02

(52) U.S. Cl. 324/760

(57) ABSTRACT

Due to the test current and the test temperature of the wafer-level reliability depend on each other in those conventional arts, the result of electromigration etc is not sure cause of the test current or the test temperature and debases the reliability of the test result. In the present invention, the electromigration test and the stress migration test of the wafer-level reliability are independently controlled, respectively. Therefore, the cause of electromigration and the stress migration can be sure resulting from the test current or the test temperature respectively. Furthermore, the isothermal heater of the present invention not only can keep a whole test wafer at a more uniform test temperature, but also can offset the electromagnetism resulted from the current of the isothermal heater by the arrangement of circuits thereof for reducing the effect of the electromagnetism.

### BACKGROUND OF THE INVENTION

1. Field of the Invention

This invention relates to a structure and a method of wafer-level reliability in a electromigration and a stress migration, and more particularly to a structure and a method with independent isothermal heater for wafer-level reliability electromigration and a stress migration test, which a test current thereof and a test temperature thereof are independent each other.

2. Description of the Prior Art

When the general public buys electric appliance, e.g.: a personal computer, etc, the public always cares about “warranty term. For a manufacturer, if the warranty term is too long, the cost of product increases. For a consumer, if the warranty term is too short, the consumer reduces the desire for buying the product. How long is the suitable warranty term of a product to maintain a profit and a reputation of the product? Hence, for a manufacturer, must estimate a lifetime of the product produced by own manufactory. The lifetime estimate can help the manufacturer understand the suitable warranty term and improve the product.

In general, the estimate is called “Reliability Estimate”. The “Reliability” can be simply described as: a duration for a product can be operated under a common state. The manufacturer employs “accelerated lifetime test” to estimate the lifetime for obtaining the estimate in a shorter time. The accelerated lifetime test is proceeded under a stern state, e.g.: a higher operating temperature, a higher operating pressure, a higher operating voltage, a higher operating current, for obtaining a operating duration under the stern state. Then, the lifetime of the product can be calculated from the operating duration with a lifetime model.

In a wafer manufacturing process of a semiconductor, the lifetime test can be divided two types, called “product reliability” and “process reliability” respectively. The product reliability means that a produced and preliminarily packaged chip is tested in a high temperature, a high pressure and a high humidity state for obtaining the lifetime. The test items include “Temperature Humidity Bias Test (THB)”, High-Temperature Operation Lifetime (HTOL)” and “Temperature Cycling Test (TC)”. The process reliability means that a preliminarily produced wafer is proceed a lifetime test aimed at a semiconductor element material for ensuring no reliability misgiving in a successive process. The test items include “Gate Oxide Integrity (GOI)” in a front-end process, “Electromigration (EM)” in a back-end process, and so on.

Reliability test methods in a semiconductor can be divided into two types that are “Wafer-Level Reliability (WLR)” and “Package-Level Reliability (PLR)”. The differences between the two test types comprise that the former directly puts the wafer in a test machine of a common producing line to test, and the latter must cut the wafer to form chips and package the chips to form test samples, then the samples inserted into a burn-in board put in a chamber under a high temperature to test.

In U.S. Pat. No. 5,625,288, it discloses high frequency reliability and failure test structures in WLR and in a part of package test. The test can measure a hot-carriers, a electromigration and a oxide breakdown. In U.S. Pat. No. 6,350,626, it discloses a method of test EM lifetime having following steps. First, a pre-characterizing step is performed to obtain parameters such as T.sub.C (the critical temperature), Wc (the critical line width), Q.sub.GB (the activation energy of grain boundary diffusion) and Q.sub.L (the activation energy of lattice diffusion) of a metal prior to the use of the test methodology for a new technology. Next, whether a real line width (W) of the metal is narrower or wider than W.sub.C is determined. For the narrower line widths, the diffusion mechanism is dominated by the Lattice diffusion only and corresponds to single activation energy (Q.sub.L). A WLR isothermal test with a relatively high temperature can be implemented to reduce the test time to as short as a few seconds. The EM lifetime (t.sub.50) under normal operating condition can be directly obtained by conversion from T.sub.test to T.sub.C by using Q.sub.L.

The main advantage of the PLR is that the test is proceeded under a temperature close to a common operating temperature. However, it is also a shortcoming of the PLR due to the test time generally about more than one month and the cut chip could not sell to bring about increasing the cost. Furthermore, a frequency of a periodical random inspection for the product is about one month at best by means of the PLR. The accidental fault product can not be efficiently detected. For example, if a new process is researched in the beginning of May and the PLR of the new process is immediately proceeded, but the test result is obtained in June. Then, the new process is improved according to the test result and the PLR for the improved process is proceeded again. The next test result is obtained until August. Therefore, a development of the new process is delayed. In contrast with the PLR, the test time of the WLR is very short. The WLR can be completed in several hours. Moreover, the wafer proceeded with the WLR is still manufactured into products. A frequency of a periodical random inspection for the product is several times every week by means of the WLR and the reliability control becomes a part of a wafer manufacture. Hence, compared with the PLR, the WLR is faster and directer. It is very important for Fab. paying attention in time. The reliability of a wafer is determined in short time with the WLR and so the follow-up can be suitably decided. It assists Fab. in reducing the manufacturing time.

An item of basic reliability test is the electromigration (EM) test. The EM means that a conducting wire (e.g. a aluminum wire) connecting respective transistors is provided in a current during a long time and the aluminum atoms are moved from a negative electrode to a positive electrode by a electron wind force. A depletion of the aluminum atoms in the negative electrode causes the circuit to open or a stacking of the aluminum atoms in the positive electrode causes the circuit to short. As time goes on, the aforementioned conditions become serious and finally the integrated circuit doesn't operate. Hence, the EM test is a basic and important test item.

An isothermal electromigration is one test type of wafer-level reliability electromigration (WLR-EM). The main principle of WLR-EM is that a conducting wire is conducted with a current that the current is far higher than of a normal operating current, e.g. several ten-fold to several hundredfold, and a rather high joule heating is brought. Under the high heating and the high current density, the failure time of the conducting wire is measured for estimating the reliability of the conducting wire. Processes in different temperatures bring an inner conducting wire to a thermal stress due to some materials therein are weaker in an inflexible strength and are larger in a coefficient of expansion. Therefore, a stress migration (SM) is brought due to a diffusion of the material therein or a destruction of the inflexible strength.

A temperature coefficient resistance TCR_{ref} of a conducting wire is obtained with the following Eq. (1).

TCR_{ref}=ΔR/(R_{ref}*ΔT) (1)

Wherein TCR_{ref} is the temperature coefficient of the resistance thereof; ΔT is a difference between a test temperature Tₜₑₛₜ and a reference temperature T_{ref}; R_{ref} is a resistance of the conducting wire in reference temperature; ΔR is a difference between a resistance in the test temperature Tₜₑₛₜ and the resistance R_{ref}.

Consequently, if only TCR is obtained, the resistance of the conducting wire is calculated from a temperature of the conducting wire with Eq. (2) or a temperature is calculated from a resistance with Eq. (2). Eq. (2) is written as:

R_{Ttest}=RT_{ref}[1+TCR_{ref}*(Tₜₑₛₜ−T_{ref})] (2)

Referring to FIG. 1, a resistance of the conducting wire is measured in a different temperature under a low current for obtaining a linear function of resistance and temperature. The joule heating can be ignored due to the low current. Then, a resistance under a high current and a room temperature is measured and a temperature of the conducting wire can be calculated with the aforementioned the linear function. Because the test temperature is maintained at a fixed temperature by adjusting the test current with a computer controlled program during the test process, it is called “Isothermal Electromigration”. An iso-current test may be proceeded with a fixed current, but the isothermal control can not be maintained simultaneously.

The exercise of the isothermal EM or iso-current EM has some misgivings in the industrial circles due to some contentions being pending, e.g.: a failure mechanism of EM. Because the test current density in EM is very high, the aluminum wire may be melted away and open due to the high temperature and not EM. Furthermore, the current shakes during the test process due to the temperature of the conducing wire maintained at a fixed temperature with a fine tuning of the current of the conducting wire or the temperature shakes during the test process due to the temperature of the conducting wire maintained at a predetermined temperature with a fixed current in the conducting wire. Moreover, the temperature in different position of the wafer is not uniform due to the circuit distribute over a wafer not uniform.

Hence, how are the current or the temperature of the conducting wire in the wafer stably maintained at a fixed current or temperature? How can the temperature be uniform? How does it confirm that the test result results from the EM or the high temperature? The aforementioned problem can be overcome with the present invention.

### SUMMARY OF THE INVENTION

In the conventional arts, it has the misgiving of the test result being resulting from the high temperature. It is an objective for present invention to provide a method and a structure for wafer-level reliability electromigration and stress migration test by a isothermal heater. The test current and the test temperature can be independently controlled with the present invention. The effect of the temperature and the current for the electromigration and stress migration can be obtained respectively for increasing the reliability and the accuracy.

It is another objective for present invention to provide the method and the structure for wafer-level reliability electromigration and stress migration test by a isothermal heater to independently control the test temperature and the test current for more stably maintaining the temperature and the current.

It is a still another objective for present invention to provide a method and a structure for wafer-level reliability electromigration and stress migration test by a isothermal heater to avoid the disproportionate temperature distribute over a wafer resulting from the disproportionate circuit distribute for reducing the effect of the disproportionate temperature distribute.

It is another objective for present invention to provide the method and the structure for wafer-level reliability electromigration and stress migration test by isothermal heater to offset an electromagnetism resulting from the test current for avoiding interference from the electromagnetism.

As aforementioned, the present invention provides a method and a structure for wafer-level reliability. An isothermal heater is formed under a test wafer and an isothermal current is provided in the isothermal heater for making the test wafer reach and maintain a test temperature to proceed a WLR-EM and SM test. Wherein, the isothermal current is different from a stress current provided in the test wafer. Therefore, the current and the test temperature resulting from the isothermal current can be independently controlled for enhancing the reliability and the accuracy of the test result. Moreover, the disproportionate temperature distribute over a wafer resulting from the disproportionate circuit distribute can be avoided for reducing the effect of the disproportionate temperature distribute. Furthermore, the electromagnetism resulting from the isothermal current can be offset for avoiding the interference from the electromagnetism.

### BRIEF DESCRIPTION OF THE DRAWINGS

FIG. 1 is a diagram of a linear function between a resistance and a temperature of a conductor;

FIG. 2 is a diagram of one preferred embodiment of the present invention;

FIGS. 3A and 3B are a lateral view and a vertical view of a another preferred embodiment, respectively; and

FIGS. 4A and 4B are a lateral view and a vertical view of a still another preferred embodiment, respectively.

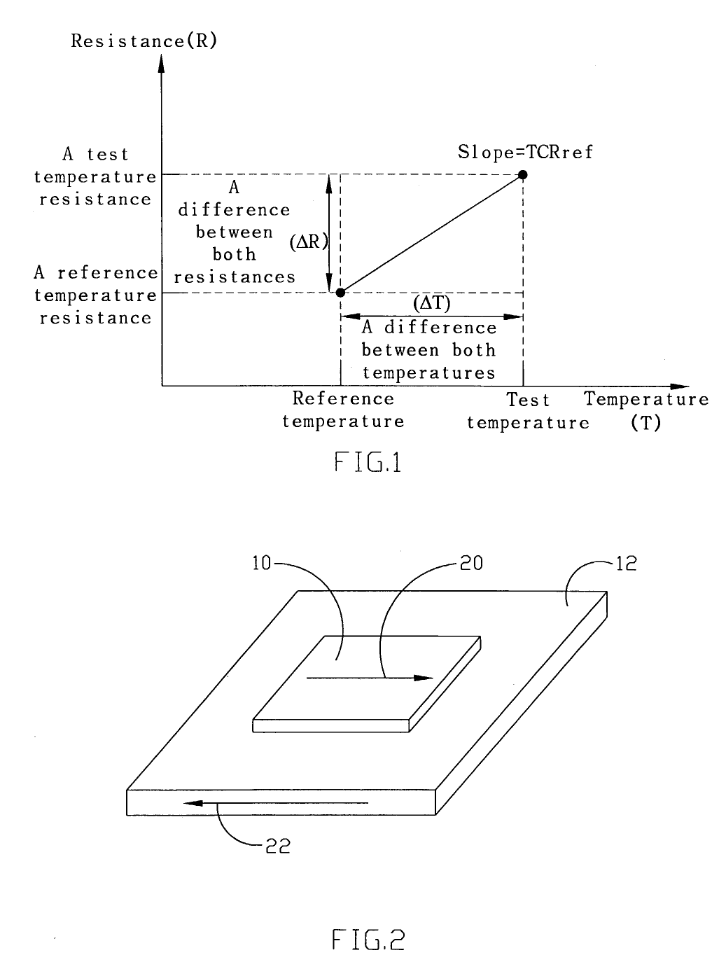

### DESCRIPTION OF THE PREFERRED EMBODIMENT

Some sample embodiments of the invention will now be described in greater detail. Nevertheless, it should be recognized that present invention can be practiced in a wide range of other embodiments besides those explicitly described, and the scope of the present invention is expressly not limited expect as specified in the accompanying claims.

Then, the components of the different elements are not shown to scale. Some dimensions of the related components are exaggerated and meaningless portions are not drawn to provide a more clear description and comprehension of the present invention.

From Eq. (2), it can be learned that the test temperature and the test current of wafer-level reliability test are relative. In other words, when the test temperature (or the test current) is fixed at a certain value, the test current (or the test temperature) also is fixed at a certain value and can not be changed. Consequently, it is hard to make sure that the main cause of the EM is the temperature or the current and the effect proportions of the temperature and the current. Furthermore, one item of the factor of the temperature and the current is fixed and the other factor must be adjusted to fix the value of the item. Therefore, the two items can not be maintained at a fixed value simultaneously. Hence, in embodiments of the present invention, it provides a extra isothermal heater to independently control the test temperature and the test current for overcoming the disadvantages in the conventional arts. Moreover, the problem of the disproportionate temperature distribute can be solved with an arrangement of circuit distribution in the isothermal heater.

Referring to FIG. 2, it is a substrate structure isothermal heater in one preferred embodiment of the present invention. A test wafer 10 is placed in an isothermal heater 12. A stress current 20 is provided in the test wafer 10. An isothermal current 22 is provided in the isothermal heater 12 for making the isothermal heater 12 reaches a predetermined test temperature. The predetermined test temperature can be achieved with the following step. First, a temperature coefficient of the resistance of the isothermal heater 12 can be obtained with Eq. (1) and then the resistance value corresponding to the predetermined test temperature can be obtained with Eq. (2). When a resistance value of the isothermal resistance reaches the corresponding resistance value, the temperature of the isothermal heater 12 is equal to the predetermined test temperature. A area of the isothermal heater 12 is more preferably than the test wafer 10 due to the test wafer 10 completely contacting with the isothermal heater 12 and reaching a uniform temperature. Moreover, a direction of the isothermal current 22 and a direction of the stress current 20 are opposite. Therefore, electromagnetisms produced by the isothermal current 22 and the stress current 20 are offset for reducing the effect of the electromagnetisms for the reliability test.

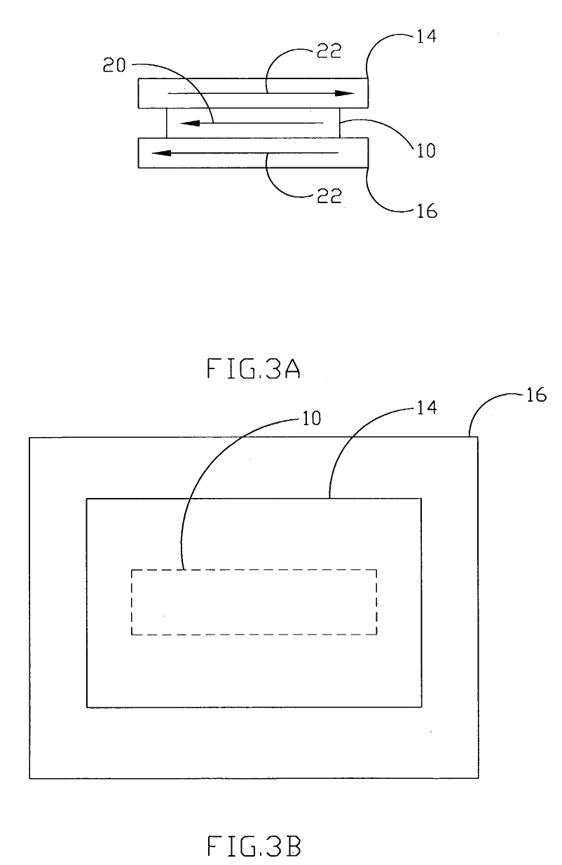

Another preferred embodiment of the present invention is a sandwich structure isothermal heater, as shown in FIG. 3A and FIG. 3B. A test wafer 10 is placed in between an isothermal heater 12. The isothermal heater 12 includes an upper heater 14 and a lower heater 16, and the test wafer 10 is sandwiched in between the upper heater 14 and the lower heater 16. A stress current 20 is provided in the test wafer 10. An isothermal current 22 is provided in the upper heater 14 and the lower heater 16 for making the isothermal heater 12 reaches a predetermined test temperature. The predetermined test temperature can be achieved with the aforementioned step of the preferred embodiment: first obtaining a resistance value corresponding to a predetermined test temperature and then the temperature of the isothermal heater 12 reaching the predetermined test temperature when a resistance of the isothermal resistance reaches the corresponding resistance. The temperature of the test wafer 10 can be more uniform with the sandwich structure. Moreover, a direction of the isothermal current 22 of the upper heater 14 and a direction of the isothermal current 22 of the lower heater 16 are opposite. Therefore, electromagnetisms produced by the upper heater 14 and the lower heater 16 are offset for reducing the effect of the electromagnetisms for the reliability test.

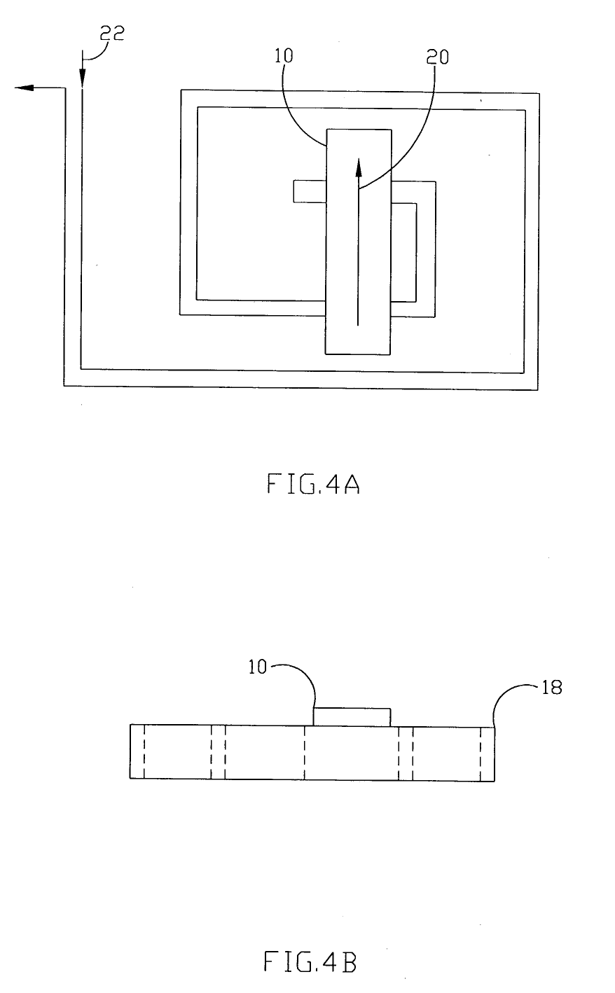

A still another preferred embodiment of the present invention is a spiral structure isothermal heater, as shown in FIG. 4A and FIG. 4B, with two layers. A test wafer 10 is placed in between a spiral isothermal heater 18. A stress current 20 is provided in the test wafer 10. An isothermal current 22 is provided in the spiral isothermal heater 18 for making the spiral isothermal heater 18 reaches a predetermined test temperature. The temperature of the test wafer 10 can be more uniform with the spiral structure. Moreover, the effect of reaching uniform temperature can be achieved by a spiral structure isothermal heater without two layers. However, a direction of the isothermal current 22 in the inner layer and a direction of the isothermal current 22 in the outer layer can be opposite. Therefore, the spiral structure isothermal heater with two layers, as shown in FIG. 4A and FIG. 4B, can offset electromagnetisms produced by the currents in the two layers for reducing the effect of the electromagnetisms for the reliability test.

In aforementioned embodiments, the isothermal heater is formed on the test wafer by means of semiconductor processes. For a different test wafer, a different isothermal heater appropriate for the test wafer is formed thereon. When the isothermal heater reaches the test temperature, the parameters, e.g.: the temperature, electric characteristics, etc, of the test wafer is measured with a measuring apparatus. The WLR test proceeds with the parameters to estimate the lifetime, the reliability and so on. Moreover, the process is improved according to the estimate.

In addition to the aforementioned isothermal structures, an isothermal structure that can achieve the isothermal effect also conforms to the concept of the present invention. The isothermal heater of WLR test in the present invention not only maintains the test wafer at a predetermined temperature for reducing the inaccuracy resulting from the disproportionate temperature, but also employs different structures according to different test wafers for offsetting the electromagnetism produced by currents. Hence, the interference resulting from the electromagnetism can be avoided for enhancing the test accuracy. The material of the isothermal heater in the present invention only satisfies that the isothermal heater is a conductor with impedance. A material of the isothermal heater is preferably a material with better heat conduction, e.g.: selected from polysilicon, silicon, copper, aluminum, tungsten, BaTiO₃ and so on.

In accordance with the present invention, the present invention provides a method and a structure for wafer-level reliability electromigration and stress migration test by isothermal heater. The stress current and the test temperature of the test wafer can be independently controlled with the present invention to independently measure the effect of the temperature and the current for the electromigration and stress migration, e.g.: measuring under a high stress current and a low temperature for eliminating the temperature effect and measuring under a low stress current and a high temperature for eliminating the current effect. The misgivings that the electromigration resulting from the current or the temperature in the conventional arts can be avoided. Furthermore, the preoblems in the conventional arts that the current shakes due to controlling the temperature at a fixed temperature or the temperature shakes due to controlling the current at a fixed current can be avoided, too. Moreover, it also avoids the disproportionate temperature distribute resulting from the disproportionate circuit distribute for reducing the inaccuracy result from the effect of the disproportionate temperature distribute.

Although specific embodiments have been illustrated and described, it will be obvious to those skilled in the art that various modifications may be made without departing from what is intended to be limited solely by the appended claims.

What is claimed is:

1. A structure for wafer-level reliability, comprising:
an isothermal heater formed under a test wafer and a current provided in said isothermal heater for making said test wafer reach and maintain a test temperature; and
a measure apparatus measuring a temperature and electric characteristics of said test wafer when said test wafer reaches a test temperature.

2. The structure for wafer-level reliability according to claim 1, wherein a material of said isothermal heater is selected from the group consisting of polysilicon, silicon, copper, aluminum, tungsten and BaTiO₃.

3. The structure for wafer-level reliability according to claim 1, wherein a structure of said isothermal heater is a substrate structure.

4. The structure for wafer-level reliability according to claim 3, wherein a direction of said current in said isothermal heater and a direction of a current provided in said test wafer are opposite.

5. The structure for wafer-level reliability according to claim 1, wherein a structure of said isothermal heater is a sandwich structure comprising an upper heater and a lower heater that are formed above and under said test wafer respectively.

6. The structure for wafer-level reliability according to claim 5, wherein a direction of a current in said upper heater and a direction of a current in said lower heater are opposite.

7. The structure for wafer-level reliability according to claim 1, wherein a structure of said isothermal heater is a spiral structure.

8. The structure for wafer-level reliability according to claim 7, wherein said spiral structure of said isothermal heater is a spiral structure with two layers, an inner layer and outer layer.

9. The structure for wafer-level reliability according to claim 8, wherein a direction of a current in said inner layer and a direction of a current in said outer layer are opposite.

10. A structure for wafer-level reliability that employs a measure apparatus measuring a temperature and electric characteristics of said test wafer when said test wafer reaches a test temperature, comprising:
an isothermal heater formed under a test wafer and a current provided in said isothermal heater for making said test wafer reach and maintain said test temperature.

11. The structure for wafer-level reliability according to claim 10, wherein a structure of said isothermal heater is a substrate structure.

12. The structure for wafer-level reliability according to claim 10, wherein a structure of said isothermal heater is a sandwich structure comprising an upper heater and a lower heater that are formed above and under said test wafer respectively.

13. The structure for wafer-level reliability according to claim 10, wherein a structure of said isothermal heater is a spiral structure.

14. A method for wafer-level reliability electromigration and stress migration test, comprising:
forming an isothermal heater under a test wafer and providing a current in said isothermal heater for making said test wafer reach and maintain a test temperature; and
measuring a temperature and electric characteristics of said test wafer when said test wafer reaches a test temperature.

15. The method for wafer-level reliability electromigration and stress migration test according to claim 14, wherein a material of said isothermal heater is selected from the group consisting of polysilicon, silicon, copper, aluminum, tungsten and BaTiO₃.

16. The method for wafer-level reliability electromigration and stress migration test according to claim 14, wherein a structure of said isothermal heater is a substrate structure.

17. The method for wafer-level reliability electromigration and stress migration test according to claim 16, wherein a direction of said current in said isothermal heater and a direction of a current provided in said test wafer are opposite.

18. The method for wafer-level reliability electromigration and stress migration test according to claim 14, wherein a structure of said isothermal heater is a sandwich structure comprising an upper heater and a lower heater that are formed above and under said test wafer respectively.

19. The method for wafer-level reliability electromigration and stress migration test according to claim 18, wherein a direction of a current in said upper heater and a direction of a current in said lower heater are opposite.

20. The method for wafer-level reliability electromigration and stress migration test according to claim 14, wherein a structure of said isothermal heater is a spiral structure.

21. The method for wafer-level reliability electromigration and stress migration test according to claim 20, wherein said spiral structure of said isothermal heater is a spiral structure with two layers of an inner layer and an outer layer.

22. The method for wafer-level reliability electromigration and stress migration test according to claim 21, wherein a direction of a current in said inner layer and a direction of a current in said outer layer are opposite.
